(19) United States
(12) Patent Application Publication
(10) Pub. No.: US 2026/0018495 A1
(43) Pub. Date: Jan. 15, 2026

(54) SEMICONDUCTOR DEVICE AND MANUFACTURING METHOD FOR SEMICONDUCTOR DEVICE

(71) Applicant: Rohm Co., Ltd., Kyoto-shi (JP)

(72) Inventors: Bin ZHANG, Kyoto-shi (JP); Taro NISHIOKA, Kyoto-shi (JP)

(21) Appl. No.: 19/331,684

(22) Filed: Sep. 17, 2025

Related U.S. Application Data
(63) Continuation of application No. PCT/JP2024/008720, filed on Mar. 7, 2024.

(30) Foreign Application Priority Data
Mar. 24, 2023 (JP) 2023-047967

(51) Int. Cl. H01L 23/495; H01L 21/48; H01L 21/56; H01L 23/00; H01L 23/31

(52) U.S. Cl. CPC H01L 23/49548; H01L 21/4825; H01L 21/4828; H01L 21/565; H01L 23/3114; H01L 23/4951; H01L 23/49531; H01L 23/562; H01L 24/13; H01L 24/16; H01L 2224/13111; H01L 2224/1312; H01L 2224/13139; H01L 2224/13155; H01L 2224/16245; H01L 2924/3512

(57) ABSTRACT

A semiconductor device comprising a terminal, a semiconductor element and a sealing resin. The semiconductor element is disposed on one side of the terminal in a first direction and electrically connected to the terminal. The sealing resin covers the semiconductor element and a part of the terminal. The sealing resin has a bottom surface disposed on an opposite side to the semiconductor element with respect to the terminal in the first direction. The terminal extends beyond the bottom surface.

### TECHNICAL FIELD

The present disclosure relates to a semiconductor device and a method of manufacturing the same.

### BACKGROUND ART

JP-A-2017-224750 discloses an example of a semiconductor device including terminals, a semiconductor element electrically connected to each of the terminals, and a sealing resin covering the semiconductor element and a part of each of the terminals. Each of the terminals has a terminal reverse surface facing one side in the thickness direction of the semiconductor element. The sealing resin has a resin reverse surface facing the same side in the thickness direction as the terminal reverse surface. The terminal reverse surface is exposed from the sealing resin so as to be flush with the resin reverse surface. The terminal reverse surface is covered with a terminal conductive layer. The terminal conductive layer improves solder wettability. With this configuration, when the semiconductor device is mounted on a wiring board, the entirety of the terminal reverse surface is covered with solder, thereby enhancing the bonding strength of the semiconductor device to the wiring board.

However, due to further circuit integration and downsizing of recent semiconductor devices, the number of terminals tends to increase, which may cause the area of each terminal reverse surface to be further reduced. This may reduce the contact area of each terminal with solder, which may result in a decrease in the bonding strength of the semiconductor device to the wiring board.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a semiconductor element and a sealing resin transparent.

FIG. 3 is a bottom view of the semiconductor device in FIG. 1.

FIG. 4 is a right-side view of the semiconductor device in FIG. 1.

FIG. 5 is a front view of the semiconductor device in FIG. 1.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a partially enlarged cross-sectional view of FIG. 6.

FIG. 10 is a cross-sectional view illustrating a step of manufacturing the semiconductor device shown in FIG. 1.

FIG. 11 is a cross-sectional view illustrating a step of manufacturing the semiconductor device shown in FIG. 1.

FIG. 12 is a cross-sectional view illustrating a step of manufacturing the semiconductor device shown in FIG. 1.

FIG. 13 is a cross-sectional view illustrating a step of manufacturing the semiconductor device shown in FIG. 1.

FIG. 14 is a cross-sectional view illustrating a step of manufacturing the semiconductor device shown in FIG. 1.

FIG. 15 is a cross-sectional view illustrating a step of manufacturing the semiconductor device shown in FIG. 1.

FIG. 16 is a cross-sectional view illustrating a step of manufacturing the semiconductor device shown in FIG. 1.

FIG. 17 is a plan view of a semiconductor device according to a second embodiment of the present disclosure, with a semiconductor element and a sealing resin transparent.

FIG. 18 is a bottom view of the semiconductor device in FIG. 17.

FIG. 19 is a cross-sectional view taken along line XIX-XIX in FIG. 17.

FIG. 20 is a cross-sectional view taken along line XX-XX in FIG. 17.

FIG. 21 is a partially enlarged cross-sectional view of FIG. 19.

### DETAILED DESCRIPTION OF EMBODIMENTS

The following describes preferred embodiments of the present disclosure in detail with reference to the drawings.

### First Embodiment

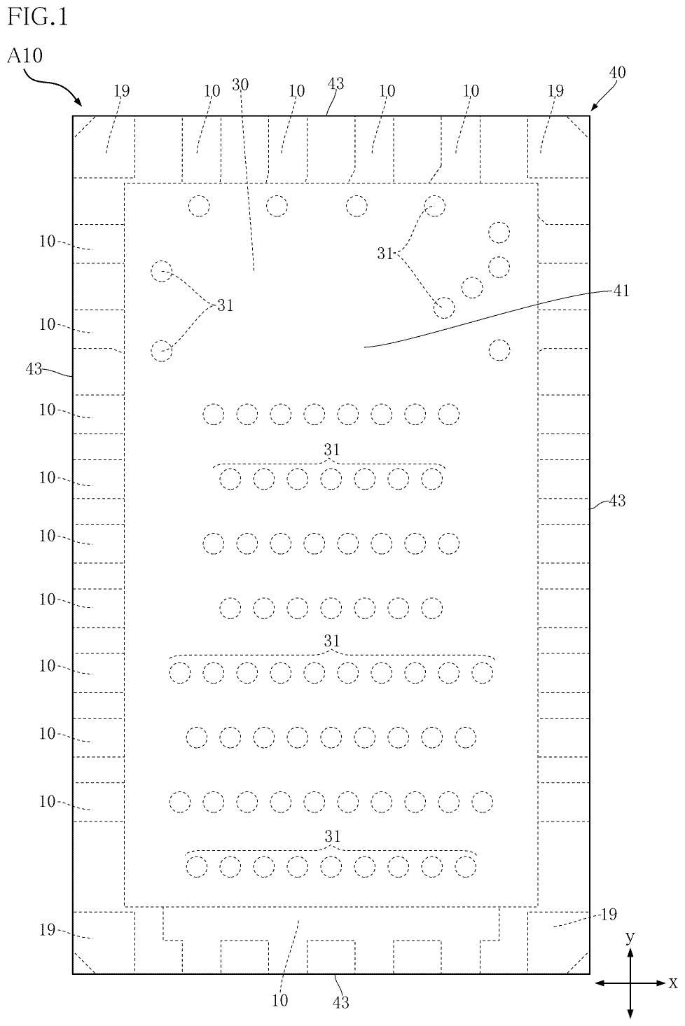

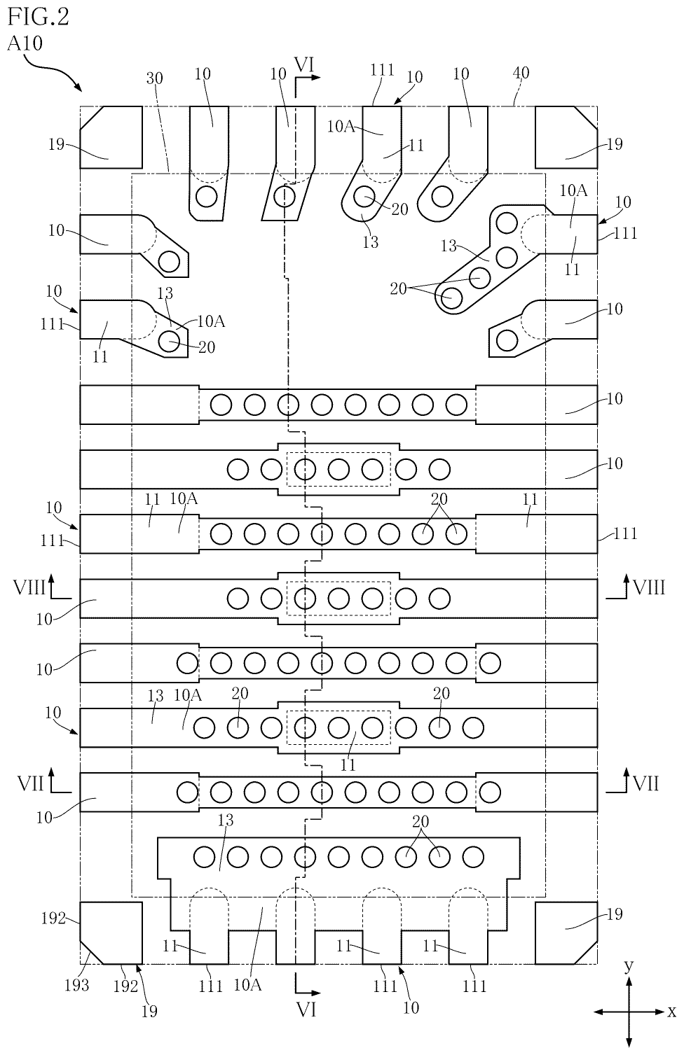

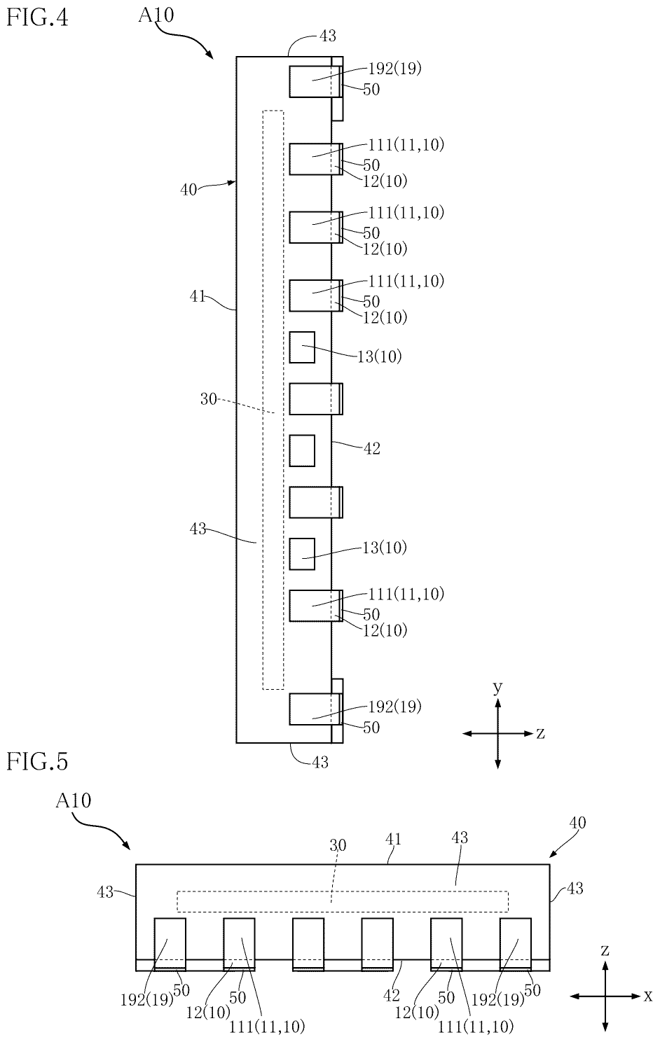

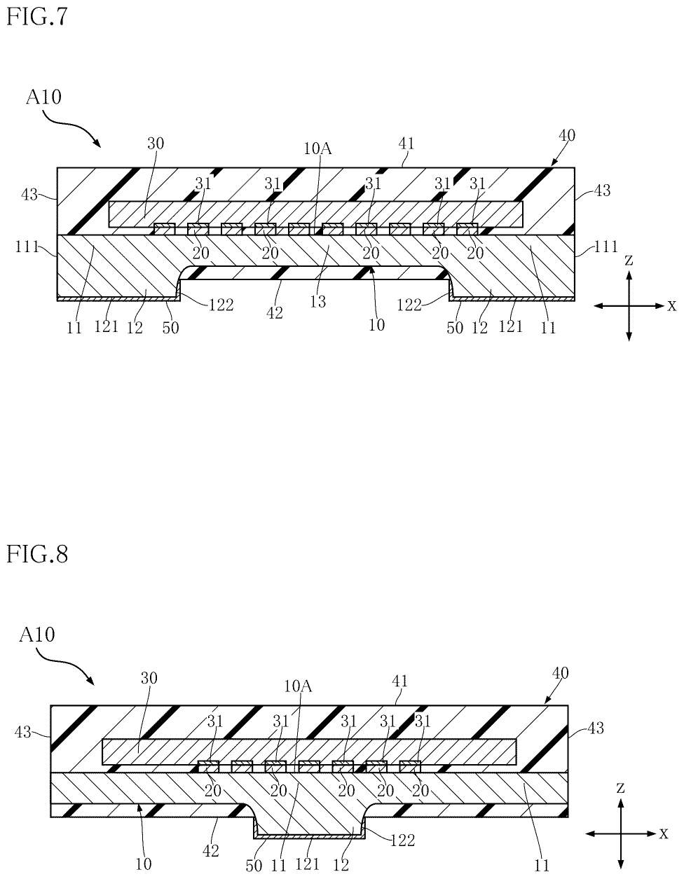

Based on FIGS. 1 to 9, a semiconductor device A10 according to a first embodiment of the present disclosure will be described. The semiconductor device A10 includes a plurality of terminals 10, four dummy terminals 19, a plurality of bonding layers 20, a semiconductor element 30, a sealing resin 40, and a plurality of covering layers 50. The semiconductor device A10 is in a form of a resin package that is surface-mounted on a wiring board. The resin package is a QFN (quad flat non-leaded package), in which a plurality of leads do not protrude from the scaling resin 40. In FIG. 2, for the sake of convenience of understanding, the semiconductor element 30 and the sealing resin 40 are shown to be transparent. In FIG. 2, the semiconductor element 30 and the sealing resin 40 are indicated by an imaginary line (two-dot chain line). Additionally, line VI-VI in FIG. 2 is shown with a one-dot chain line.

In the explanation of the semiconductor device A10, for the sake of convenience, the normal direction of the obverse surface 10A of each of terminals 10, which will be described later, is referred to as a “first direction z”. One direction orthogonal to the first direction z is referred to as a “second direction x”. A direction orthogonal to the first direction z and the second direction x is referred to as a “third direction y”. As shown in FIG. 1, the semiconductor device A10 is rectangular in shape as viewed in the first direction z (i.e., in plan view).

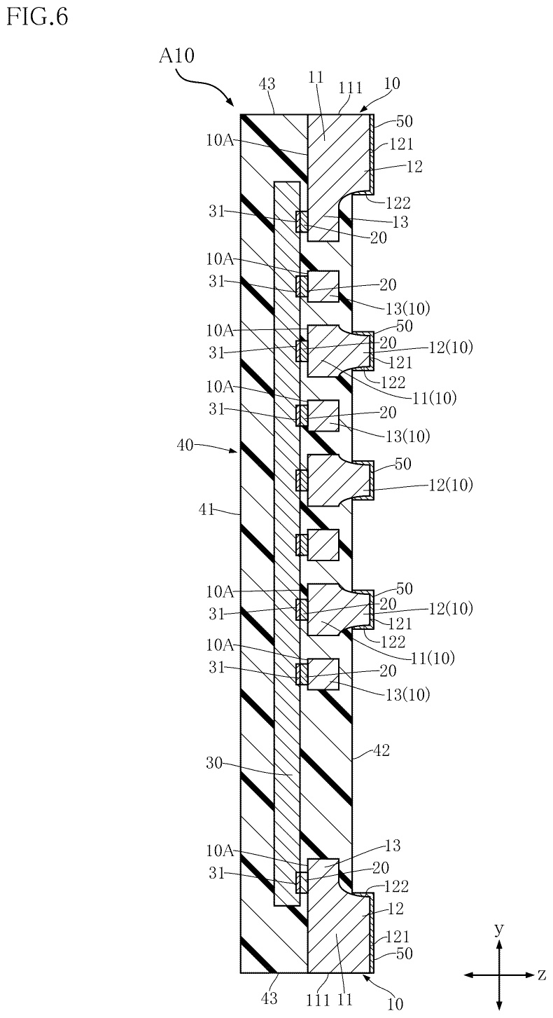

As shown in FIGS. 6 to 8, the sealing resin 40 covers the semiconductor element 30 and a part of each of the terminals 10. The scaling resin 40 has electrical insulation properties. One example of the material for the scaling resin 40 is black epoxy resin.

As shown in FIGS. 4 to 8, the sealing resin 40 has a top surface 41, a bottom surface 42, and a plurality of side surfaces 43. The top surface 41 and the bottom surface 42 mutually face opposite sides in the first direction z. In the first direction z, the bottom surface 42 is disposed on an opposite side to the semiconductor element 30 with respect to the terminals 10. Each of the side surfaces 43 is located between the top surface 41 and the bottom surface 42 in the first direction z. Each of the side surfaces 43 faces a direction orthogonal to the first direction z.

As shown in FIG. 9, the bottom surface 42 is formed as a rough surface. The bottom surface 42 has a surface roughness that is greater than a surface roughness of the top surface 41.

As shown in FIGS. 6 to 8, the terminals 10 support the semiconductor element 30. Each of the terminals 10 forms a conductive path between the semiconductor element 30 and a wiring board on which the semiconductor device A10 is mounted. The terminals 10 contain copper (Cu). The terminals 10 are obtained from a common lead frame.

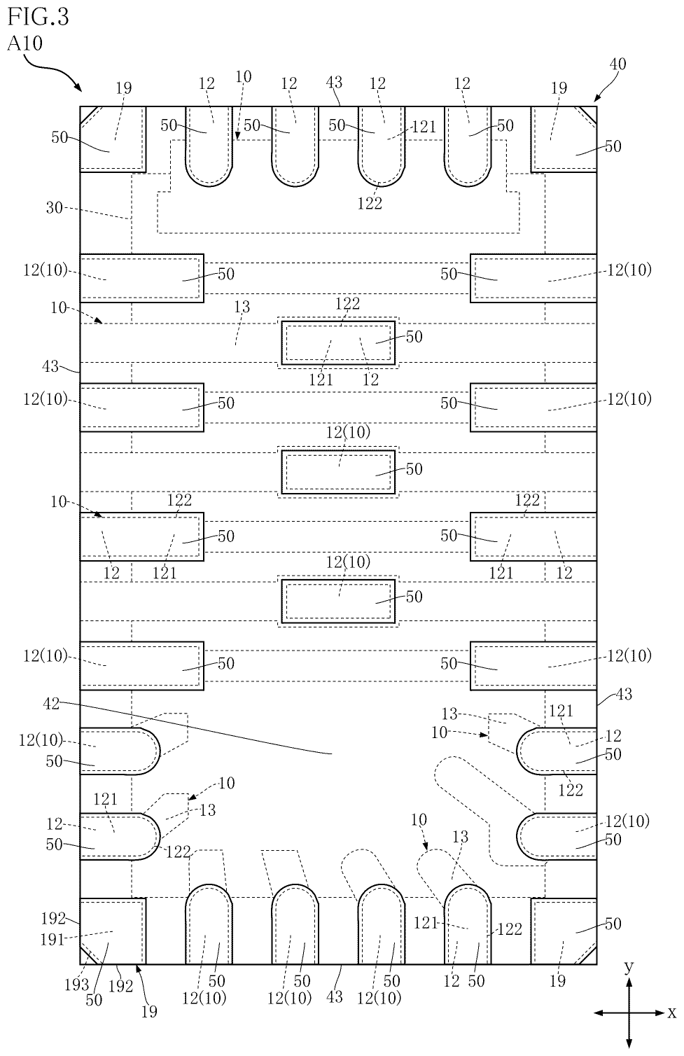

As shown in FIGS. 2 and 3, each of the terminals 10 includes at least one base portion 11, at least one projection portion 12, and an extended portion 13. Each of the terminals has the same number of projection portions 12 as the base portions 11. Each of the terminals 10 has an obverse surface 10A that faces the same side as the top surface 41 of the scaling resin 40 in the first direction z. The obverse surface 10A faces the semiconductor element 30. Each of the base portion 11 and the extended portion 13 includes the obverse surface 10A.

As shown in FIGS. 6 and 7, the base portion 11 is housed in the sealing resin 40. The base portion 11 has an end surface 111. The end surface 111 faces a direction orthogonal to the first direction z. As shown in FIGS. 4 to 7, the end surface 111 is exposed from one of the side surfaces 43 of the sealing resin 40. The end surface 111 is flush with the corresponding side surface 43.

As shown in FIGS. 6 to 8, the projection portion 12 is connected to the base portion 11. The projection portion 12 extends beyond the bottom surface 42 of the sealing resin 40. The projection portion 12 has a dimension in the first direction z that is smaller than a dimension of the base portion 11 in the first direction z.

As shown in FIGS. 3 and 6 to 8, the projection portion 12 includes a mounting surface 121 and a circumferential surface 122. The mounting surface 121 faces the same side as the bottom surface 42 of the sealing resin 40 in the first direction z. As viewed in the first direction z, the entirety of the mounting surface 121 overlaps with the obverse surface 10A of the base portion 11. The circumferential surface 122 is located between the mounting surface 121 and the end surface 111 of the base portion 11 in the first direction z. The circumferential surface 122 surrounds the mounting surface 121. As viewed in the first direction z, the entirety of the circumferential surface 122 overlaps with the obverse surface 10A of the base portion 11. In the semiconductor device A10, the circumferential surface 122 is connected to the end surface 111.

As shown in FIG. 9, the circumferential surface 122 of each of the terminals 10 is a curved surface recessed inward of the terminal 10. The projection portion 12 includes a boundary surface 123 that connects the mounting surface 121 and the circumferential surface 122. In each of the terminals 10, the boundary surface 123 projects outward from the terminal 10.

As shown in FIGS. 2 and 6 to 8, the extended portion 13 extends from the base portion 11 in a direction orthogonal to the first direction z. The extended portion 13 is spaced apart from the bottom surface 42 of the sealing resin 40. The extended portion 13 is held between the sealing resin 40 in the first direction z. The extended portion 13 of at least one of the terminals 10 is exposed from one of the side surfaces 43 of the sealing resin 40.

As shown in FIG. 2, the four dummy terminals 19 are disposed at four corners of the semiconductor device A10. The four dummy terminals 19 differ from the terminals 10 in that they are not electrically connected to the semiconductor element 30. Each of the four dummy terminals 19 extends beyond the bottom surface 42 of the sealing resin 40.

As shown in FIGS. 2 and 3, each of the four dummy terminals 19 includes a first surface 191, two second surfaces 192, and a third surface 193. The first surface 191 faces the same side as the bottom surface 42 of the sealing resin 40 in the first direction z. Each of the two second surfaces 192 faces a direction orthogonal to the first direction z. Each of the two second surfaces 192 is exposed from the corresponding side surface 43 of the sealing resin 40. The third surface 193 faces a direction orthogonal to the first direction z, and is located between the two second surfaces 192. The third surface 193 is inclined with respect to each of the second direction x and the third direction y. The third surface 193 is covered with the sealing resin 40.

As shown in FIGS. 2 and 6 to 8, each of the bonding layers 20 is mounted on the obverse surface 10A of one of the terminals 10. Each of the bonding layers 20 is in contact with the corresponding obverse surface 10A. The bonding layers 20 contain nickel (Ni), tin (Sn), and silver (Ag). The bonding layers 20 may alternatively contain nickel, tin, and antimony (Sb).

As shown in FIGS. 6 to 8, the semiconductor element 30 is mounted on the terminals 10. The semiconductor element 30 may be an LSI (Large Scale Integration). The semiconductor element 30 has a plurality of electrodes 31.

As shown in FIGS. 6 to 8, each of the electrodes 31 faces the obverse surface 10A of one of the terminals 10. Each of the electrodes 31 is conductively bonded to the obverse surface 10A of one of the terminals 10 via the corresponding bonding layer 20. Hence, the semiconductor element 30 is electrically connected to the terminals 10.

As shown in FIGS. 3 to 8, the covering layers 50 are externally exposed. Each of the covering layers 50 covers the mounting surface 121 and the circumferential surface 122 of the projection portion 12 of one of the terminals 10, or the first surface 191 of one of the dummy terminals 19.

The covering layers 50 are conductive. The covering layers 50 are conductively bonded to a wiring board via solder, so that the semiconductor device A10 is mounted on a wiring board. Each of the covering layers 50 contains a metal element. The metal element is either tin or gold.

Furthermore, each of the covering layers 50 may include a plurality of metal layers. The metal layers are laminated in order from a nickel layer to a gold (Au) layer from either the projection portion 12 of the corresponding terminal 10 or the first surface 191 of the corresponding dummy terminal 19. Alternatively, the metal layers may include a palladium (Pd) layer interposed between the nickel layer and the gold layer.

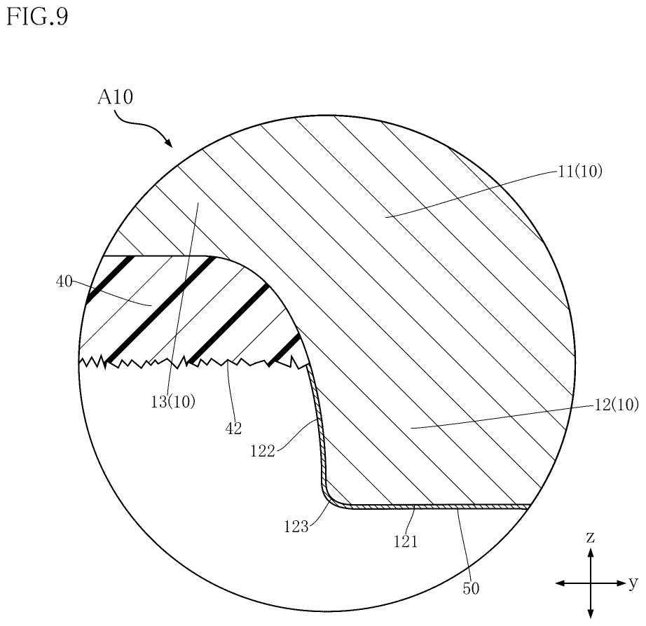

Next, an example of a method of manufacturing the semiconductor device A10 will be described based on FIGS. 10 to 16. Here, the cross-sectional positions of FIGS. 10 to 16 are identical to the cross-sectional position shown in FIG. 7.

First, as shown in FIG. 10, a part of a lead frame is removed to form a plurality of terminals 81. Each of the terminals 81 has an obverse surface 81A facing one side in the first direction z. The terminals 81 are formed by wet etching and removing a part of the lead frame located on the side opposite to the side on which the obverse surfaces 81A face in the first direction z. This step forms the terminals 81 having at least one first portion 811 and a second portion 812. The first portion 811 corresponds to a base portion 11 and a projection portion 12 of a terminal 10. The second portion 812 corresponds to an extended portion 13 of a terminal 10.

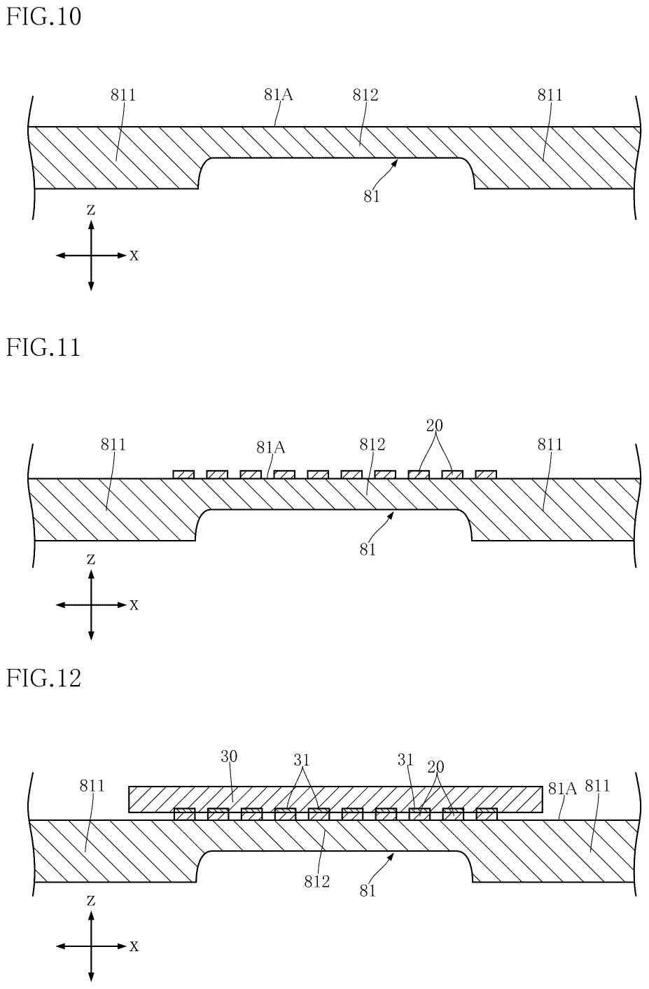

Next, as shown in FIG. 11, the bonding layers 20 are formed on the respective obverse surfaces 81A of the terminals 81. The bonding layers 20 are formed by performing photolithography patterning on the obverse surfaces 81A and then depositing a plurality of metal layers via electroplating using the terminals 81 as conductive paths.

Next, as shown in FIG. 12, each of the electrodes 31 of the semiconductor element is conductively bonded to the respective terminals 81. The semiconductor element 30 is conductively bonded by flip-chip bonding. The conductive bonding of the semiconductor element 30 is achieved by temporarily attaching the electrodes 31 to the respective bonding layers 20, and then melting and solidifying the bonding layers 20 through reflow.

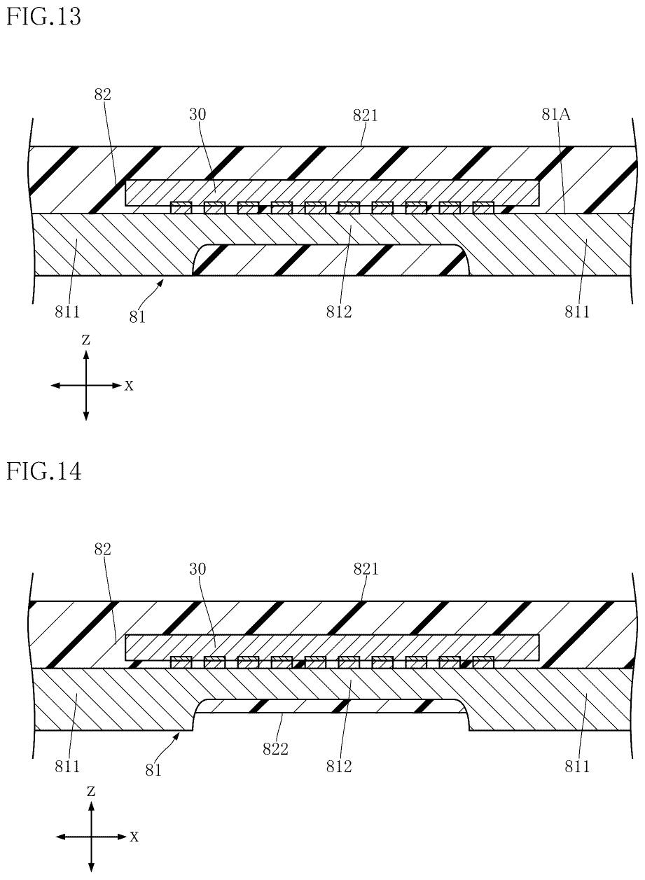

Next, as shown in FIGS. 13 and 14, a sealing resin 82 is formed so as to cover the semiconductor element 30 and a part of each of the terminals 81. First, as shown in FIG. 13, the sealing resin 82 is disposed to cover a part of each of the terminals 81 and the semiconductor element 30. This step forms the sealing resin 82 having a top surface 821. The top surface 821 faces the same side as the obverse surface 81A of each of the terminals 81 in the first direction z. The top surface 821 corresponds to the top surface 41 of the scaling resin 40.

Next, as shown in FIG. 14, a part of the sealing resin 82 on the opposite side to the semiconductor element 30 with respect to the terminals 81 in the first direction z is removed. This removal forms a bottom surface 822, so that the first portions 811 of the terminals 81 extends beyond the bottom surface 822 of the sealing resin 82. The bottom surface 822 faces the opposite side to the top surface 821 in the first direction z. The bottom surface 822 corresponds to the bottom surface 42 of the sealing resin 40. As the removal method, for example, wet blasting may be applied. Wet blasting is a technique in which a blast treatment is performed using a mixture of abrasive material (e.g., silica sand) and water. Wet blasting results in the bottom surface 822 having a surface roughness that is greater than a surface roughness of the top surface 821.

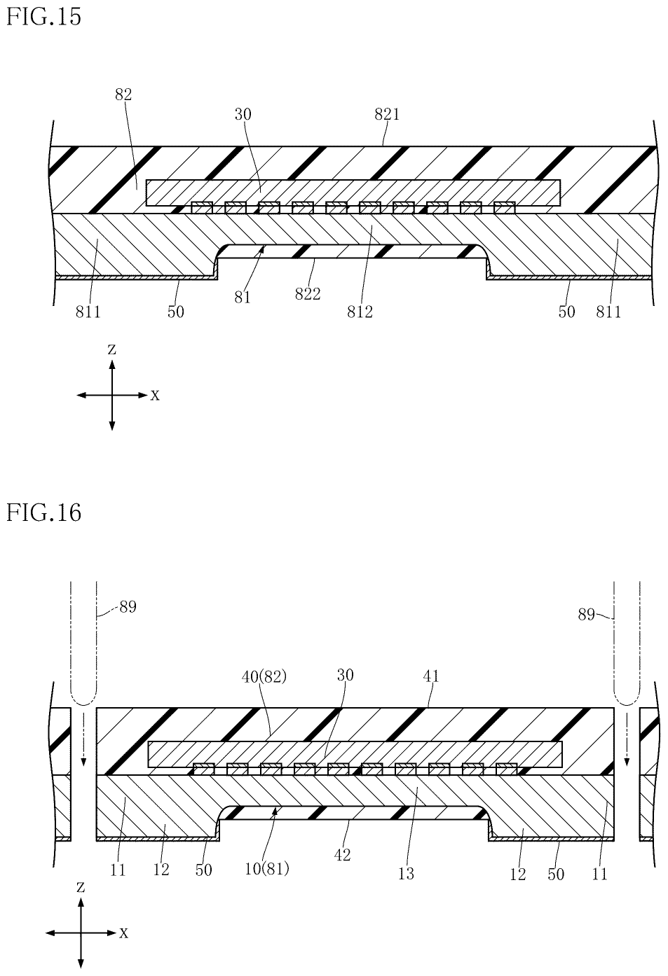

Next, as shown in FIG. 15, after smoothing the surfaces of the first portions 811 of the terminals 81 protruding outward from the bottom surface 822 of the sealing resin 82 by wet etching, a plurality of covering layers 50 individually covering the smoothed surfaces are formed. The covering layers 50 are formed by electroplating using the terminals 81 as conductive paths. Alternatively, the covering layers 50 may be formed by electroless plating.

Finally, as shown in FIG. 16, the terminals 81 and the sealing resin 82 are cut using a blade 89. In this step, the terminals 81 and the sealing resin 82 are cut in a grid pattern along each of the second direction x and the third direction y. Through this step, the terminals 81 serve as the terminals 10, and the sealing resin 82 serves as the sealing resin 40. Through the above steps, the semiconductor device A10 is obtained.

Next, operative effects of the semiconductor device A10 will be described.

The semiconductor device A10 includes the terminal 10, the semiconductor element disposed on one side of the terminal 10 in the first direction z and electrically connected to the terminal 10, and the sealing resin 40 covering the semiconductor element 30 and a part of the terminal 10. The sealing resin 40 has the bottom surface 42 disposed on an opposite side to the semiconductor element 30 with respect to the terminal 10 in the first direction z. The terminal 10 extends beyond the bottom surface 42. Such a configuration increases the contact area of the terminal 10 with solder when the semiconductor device A10 is mounted on a wiring board. Therefore, it is possible to improve bonding strength of the semiconductor device A10 to the wiring board.

The projection portion 12 of the terminal 10 has a dimension in the first direction z that is smaller than a dimension of the base portion 11 of the terminal 10 in the first direction z. Such a configuration can avoid an increase in the dimension of the semiconductor device A10 in the first direction z.

The projection portion 12 of the terminal 10 has the mounting surface 121 that faces the same side as the bottom surface 42 of the sealing resin 40 in the first direction z. The entirety of the mounting surface 121 overlaps with the obverse surface 10A of the terminal as viewed in the first direction z. Such a configuration can avoid an increase in the dimension of the terminal 10 in a direction orthogonal to the first direction z.

The projection portion 12 of the terminal 10 has the circumferential surface 122 that is located between the mounting surface 121 and the end surface 111 of the base portion 11 of the terminal 10 in the first direction z. The circumferential surface 122 surrounds the mounting surface 121. As viewed in the first direction z, the entirety of the circumferential surface 122 overlaps with the obverse surface 10A of the terminal 10. With this configuration, the circumferential surface 122 is substantially perpendicular to the mounting surface 121. Hence, when the semiconductor device A10 is mounted on a wiring board, solder tends to climb up the circumferential surface 122, thereby increasing the amount of solder in contact with the projection portion 12. Therefore, it is possible to improve bonding strength of the semiconductor device A10 to the wiring board, and the bonding state of the semiconductor device A10 to the wiring board can be easily confirmed by visual inspection.

The semiconductor device A10 further includes the covering layer 50 that covers the mounting surface 121 and the circumferential surface 122 of the projection portion 12. The covering layer 50 contains a metal element of either tin or gold. Such a configuration improves solder wettability to the projection portion 12 when the semiconductor device A10 is mounted on a wiring board. This is advantageous for preventing a reduction in the contact area between the projection portion 12 and the solder.

In the manufacturing method of the semiconductor device A10, as shown in FIG. 14, during the step of forming the sealing resin 82, after covering the semiconductor element 30 with the sealing resin 82, a part of the sealing resin 82 on the opposite side to the semiconductor element 30 with respect to the terminals 81 in the first direction z is removed. As a result, a part of the terminal 81 extends beyond the sealing resin 82. Through this manufacturing method, it is possible to form the projection portion 12 of the terminal 10 entirely covered with the covering layer 50, without requiring the two-step cutting process disclosed in JP-A-2017-224750. Therefore, this is advantageous for simplifying the manufacturing process.

The bottom surface 42 of the sealing resin 40 has a surface roughness that is greater than a surface roughness of the top surface 41 of the sealing resin 40. Such a configuration reflects a trace left by the removal of a part of the sealing resin 82 during the manufacturing process of the semiconductor device A10 as shown in FIG. 14.

The projection portion 12 of the terminal 10 includes the boundary surface 123 connecting the mounting surface 121 and the circumferential surface 122. The boundary surface 123 projects outward from the terminal 10. This configuration prevents resin debris from adhering to the projection portion 12 during the step of removing a part of the sealing resin 82, as shown in FIG. 14, even though the circumferential surface 122 is recessed inward of the terminal 10. This is advantageous for preventing a reduction in the contact area between the projection portion 12 and the solder when the semiconductor device A10 is mounted on a wiring board. This configuration is achieved in the manufacturing of the semiconductor device A10 by smoothing, through wet etching, the surface of a part of the terminal 81 extending beyond the sealing resin 82 during the step of forming the covering layer 50, as shown in FIG. 15.

The semiconductor device A10 further includes the four dummy terminals 19 disposed at four corners of the semiconductor device A10 as viewed in the first direction z. The four dummy terminals 19 are not electrically connected to the semiconductor element 30. Such a configuration can concentrate thermal stress, which is caused by heat generated in the semiconductor device A10, on the four dummy terminals 19. This reduces the occurrence of cracks in solder that bonds the terminal 10 to a wiring board.

### Second Embodiment

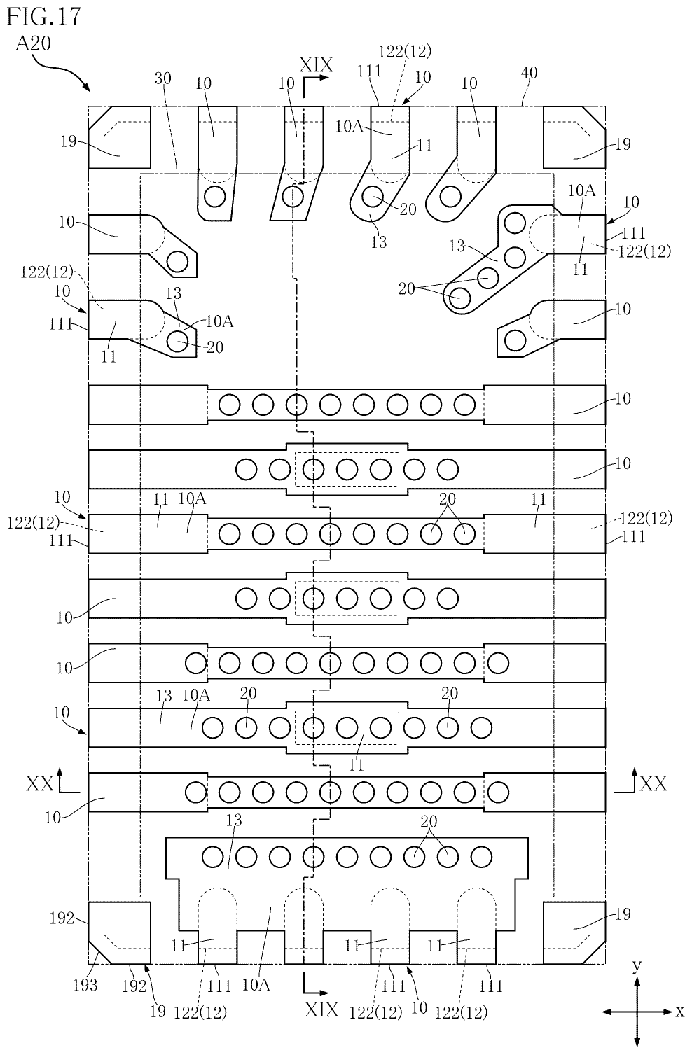

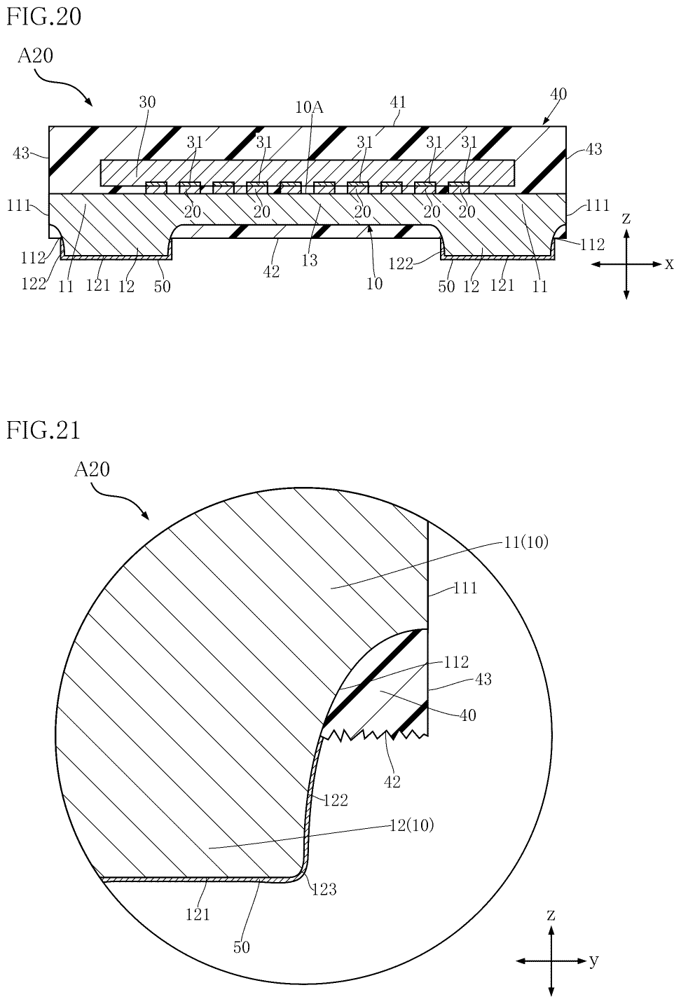

A semiconductor device A20 according to a second embodiment of the present disclosure will be described based on FIGS. 17 to 21. In these figures, elements identical or similar to those of the semiconductor device A10 described above are marked with the same symbols, and redundant descriptions are omitted. In FIG. 17, for the sake of convenience of understanding, the semiconductor element 30 and the sealing resin 40 are shown to be transparent. In FIG. 17, the semiconductor element 30 and the sealing resin are indicated by an imaginary line (two-dot chain line). Additionally, line XIX-XIX in FIG. 17 is shown with a one-dot chain line.

The semiconductor device A20 differs from the semiconductor device A10 in the configuration of the terminals 10.

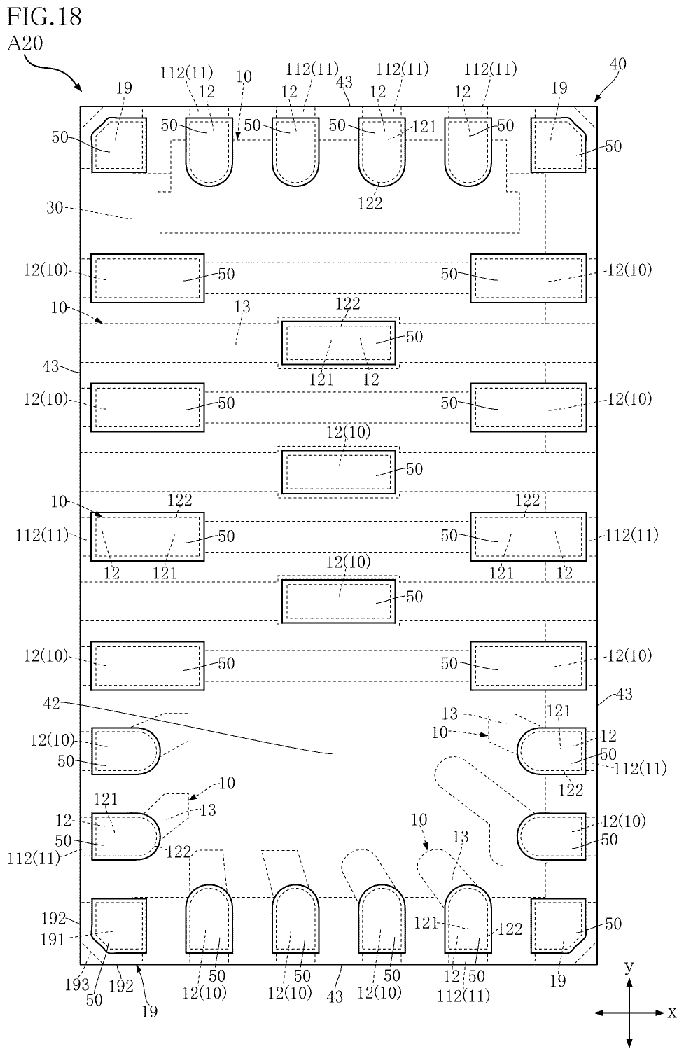

As shown in FIGS. 18 to 20, as viewed in the first direction z, the mounting surface 121 of the projection portion 12 of each terminal 10 is spaced apart from the bottom surface 42 of the sealing resin 40.

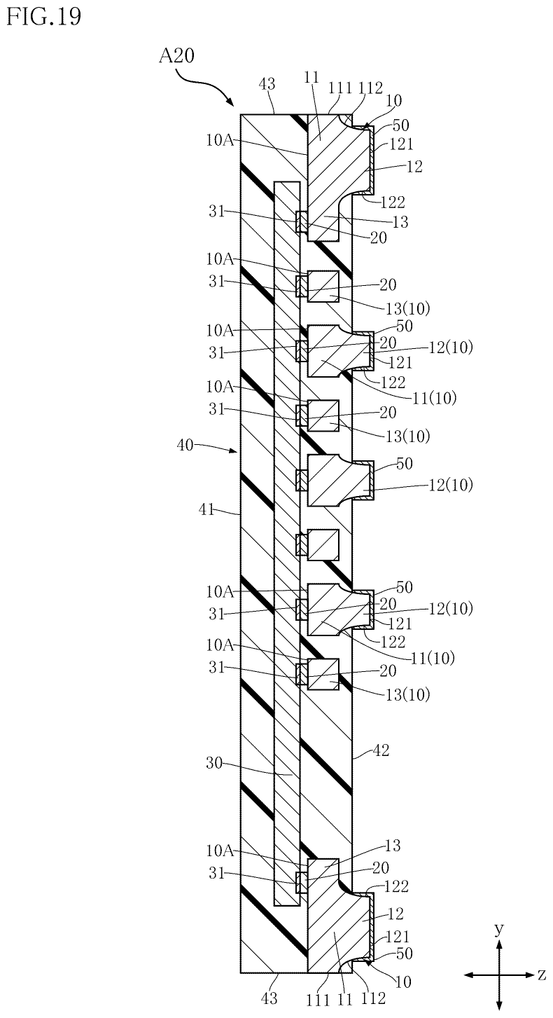

As shown in FIGS. 19 to 21, the end surface 111 of the base portion 11 of each terminal 10 is spaced apart from the bottom surface 42 of the scaling resin 40.

As shown in FIGS. 18 to 21, the base portion 11 of each terminal 10 has an intermediate surface 112. The intermediate surface 112 is connected to the end surface 111 of the base portion 11 and the circumferential surface 122 of the corresponding projection portion 12 of the terminal 10. As viewed in the first direction z, the entirety of the intermediate surface 112 overlaps with the obverse surface 10A of the base portion 11. In each terminal 10, the intermediate surface 112 is a curved surface recessed inward of the terminal 10. The intermediate surface 112 is covered with the sealing resin 40.

Next, operative effects of the semiconductor device A20 will be described.

The semiconductor device A20 includes the terminal 10, the semiconductor element disposed on one side of the terminal 10 in the first direction z and electrically connected to the terminal 10, and the sealing resin 40 covering the semiconductor element 30 and a part of the terminal 10. The sealing resin 40 has the bottom surface 42 disposed on an opposite side to the semiconductor element 30 with respect to the terminal 10 in the first direction z. The terminal 10 extends beyond the bottom surface 42. Therefore, with this configuration, it is possible to improve bonding strength of the semiconductor device A20 to a wiring board. In addition, the semiconductor device A20 may have a configuration in common with the semiconductor device A10, thereby achieving the same effect as the semiconductor device A10.

In the semiconductor device A20, as viewed in the first direction z, the mounting surface 121 of the projection portion 12 of the terminal 10 is spaced apart from the bottom surface 42 of the sealing resin 40. Such a configuration restricts solder from climbing up the end surface 111 of the base portion 11 of the terminal 10, which is exposed from the sealing resin 40, when the semiconductor device A20 is mounted on a wiring board. This is advantageous for reducing erosion of the terminal 10 by solder.

In the semiconductor device A20, the base portion 11 of the terminal 10 has the intermediate surface 112 connected to the end surface 111 of the base portion 11 and the circumferential surface 122 of the projection portion 12. The intermediate surface 112 is recessed inward of the terminal 10 and is covered with the sealing resin 40. Such a configuration restricts solder from climbing from the circumferential surface 122 to the end surface 111 when the semiconductor device A20 is mounted on a wiring board. Hence, erosion of the terminal 10 by solder can be more effectively reduced.

The present disclosure is not limited to the embodiments described above. The specific configurations of each component of the present disclosure may be modified in various ways.

The present disclosure includes the embodiments described in the following clauses.
Clause 1.

A semiconductor device comprising:
a terminal;
a semiconductor element disposed on one side of the terminal in a first direction and electrically connected to the terminal; and
a sealing resin covering the semiconductor element and a part of the terminal,
wherein the sealing resin has a bottom surface disposed on an opposite side to the semiconductor element with respect to the terminal in the first direction, and
the terminal extends beyond the bottom surface.
Clause 2.

The semiconductor device according to clause 1, wherein the terminal includes a base portion and a projection portion connected to the base portion,
the base portion is housed in the sealing resin,
the projection portion extends beyond the bottom surface, and
the base portion has an end surface facing a direction orthogonal to the first direction.
Clause 3.

The semiconductor device according to clause 2, wherein the end surface is exposed from the sealing resin.
Clause 4.

The semiconductor device according to clause 3, wherein the projection portion has a dimension in the first direction that is smaller than a dimension of the base portion in the first direction.
Clause 5.

The semiconductor device according to clause 4, wherein the sealing resin has a top surface facing away from the bottom surface in the first direction, and
the bottom surface has a surface roughness that is greater than a surface roughness of the top surface.
Clause 6.

The semiconductor device according to clause 5, wherein the terminal has an obverse surface facing the same direction as the top surface in the first direction,
the projection portion has a mounting surface facing the same direction as the bottom surface in the first direction, and
the entirety of the mounting surface overlaps with the obverse surface as viewed in the first direction.
Clause 7.

The semiconductor device according to clause 6, wherein the projection portion has a circumferential surface located between the mounting surface and the end surface in the first direction, and
the entirety of the circumferential surface overlaps with the obverse surface as viewed in the first direction.
Clause 8.

The semiconductor device according to clause 7, wherein the circumferential surface is recessed inward of the terminal.
Clause 9.

The semiconductor device according to clause 8, wherein the projection portion includes a boundary surface connecting the mounting surface and the circumferential surface, and
the boundary surface projects outward from the terminal.
Clause 10.

The semiconductor device according to clause 7, wherein the mounting surface is spaced apart from a peripheral edge of the bottom surface as viewed in the first direction.
Clause 11.

The semiconductor device according to clause 10, wherein the end surface is spaced apart from the bottom surface.
Clause 12.

The semiconductor device according to clause 11, wherein the base portion includes an intermediate surface connected to the end surface and the circumferential surface,
the intermediate surface is recessed inward of the terminal and is covered with the sealing resin.
Clause 13.

The semiconductor device according to any one of clauses 7 to 12, wherein the terminal has an extended portion extending from the base portion in a direction orthogonal to the first direction,
each of the base portion and the extended portion includes the obverse surface, and
the extended portion is spaced apart from the bottom surface.
Clause 14.

The semiconductor device according to clause 13, wherein the semiconductor element has an electrode facing the obverse surface, and
the electrode is conductively bonded to the obverse surface.
Clause 15.

The semiconductor device according to clause 14, further comprising a covering layer that covers the mounting surface and the circumferential surface,
wherein the covering layer contains a metal element.
Clause 16.

The semiconductor device according to clause 15, wherein the metal element includes tin or gold.
Clause 17.

A method of manufacturing a semiconductor device comprising:
forming a terminal;
conductively bonding a semiconductor element to the terminal; and
forming a sealing resin,
wherein the forming of the sealing resin includes covering the semiconductor element with the sealing resin, and then removing a part of the sealing resin on the opposite side to the semiconductor element with respect to the terminal in the first direction, such that a part of the terminal extends beyond the sealing resin.
Clause 18.

The method of manufacturing a semiconductor device according to clause 17, wherein the forming of the terminal includes forming the terminal by removing a part of a lead frame by etching.

### REFERENCE NUMERALS

A10, A20: Semiconductor device, 10: Terminal, 10A: Obverse surface, 11: Base portion, 111: End surface, 112: Intermediate surface, 12: Projection portion, 121: Mounting surface, 122: Circumferential surface, 123: Boundary surface, 13: Extended portion, 19: Dummy terminal, 191: First surface, 192: Second surface, 193: Third surface, 20: Bonding layer, 30: Semiconductor element, 31: Electrode, 40: Sealing resin, 41: Top surface, 42: Bottom surface, 43: Side surface, 50: Covering layer, 81: Terminal, 81A: Obverse surface, 811: First portion, 812: Second portion, 89: Blade, z: First direction, x: Second direction, y: Third direction

1. A semiconductor device comprising:
a terminal;
a semiconductor element disposed on one side of the terminal in a first direction and electrically connected to the terminal; and
a sealing resin covering the semiconductor element and a part of the terminal,
wherein the sealing resin has a bottom surface disposed on an opposite side to the semiconductor element with respect to the terminal in the first direction, and
the terminal extends beyond the bottom surface.

2. The semiconductor device according to claim 1, wherein the terminal includes a base portion and a projection portion connected to the base portion,
the base portion is housed in the sealing resin,
the projection portion extends beyond the bottom surface, and
the base portion has an end surface facing a direction orthogonal to the first direction.

3. The semiconductor device according to claim 2, wherein the end surface is exposed from the sealing resin.

4. The semiconductor device according to claim 3, wherein the projection portion has a dimension in the first direction that is smaller than a dimension of the base portion in the first direction.

5. The semiconductor device according to claim 4, wherein the sealing resin has a top surface facing away from the bottom surface in the first direction, and
the bottom surface has a surface roughness that is greater than a surface roughness of the top surface.

6. The semiconductor device according to claim 5, wherein the terminal has an obverse surface facing the same direction as the top surface in the first direction,
the projection portion has a mounting surface facing the same side as the bottom surface in the first direction, and
the entirety of the mounting surface overlaps with the obverse surface as viewed in the first direction.

7. The semiconductor device according to claim 6, wherein the projection portion has a circumferential surface located between the mounting surface and the end surface in the first direction, and
the entirety of the circumferential surface overlaps with the obverse surface as viewed in the first direction.

8. The semiconductor device according to claim 7, wherein the circumferential surface is recessed inward of the terminal.

9. The semiconductor device according to claim 8, wherein the projection portion has a boundary surface connecting the mounting surface and the circumferential surface, and
the boundary surface projects outward from the terminal.

10. The semiconductor device according to claim 7, wherein the mounting surface is spaced apart from a peripheral edge of the bottom surface as viewed in the first direction.

11. The semiconductor device according to claim 10, wherein the end surface is spaced apart from the bottom surface.

12. The semiconductor device according to claim 11, wherein the base portion has an intermediate surface connected to the end surface and the circumferential surface, and
the intermediate surface is recessed inward of the terminal and is covered with the sealing resin.

13. The semiconductor device according to claim 7, wherein the terminal has an extended portion extending from the base portion in a direction orthogonal to the first direction,
each of the base portion and the extended portion includes the obverse surface, and
the extended portion is spaced apart from the bottom surface.

14. The semiconductor device according to claim 13, wherein the semiconductor element has an electrode facing the obverse surface, and
the electrode is conductively bonded to the obverse surface.

15. The semiconductor device according to claim 14, further comprising a covering layer that covers the mounting surface and the circumferential surface,
wherein the covering layer contains a metal element.

16. The semiconductor device according to claim 15, wherein the metal element includes tin or gold.

17. A method of manufacturing a semiconductor device comprising:
forming a terminal;
conductively bonding a semiconductor element to the terminal; and
forming a sealing resin,
wherein the forming of the sealing resin includes covering the semiconductor element with the sealing resin, and then removing a part of the sealing resin on the opposite side to the semiconductor element with respect to the terminal in the first direction, such that a part of the terminal extends beyond the sealing resin.

18. The method of manufacturing a semiconductor device according to claim 17, wherein the forming of the terminal includes forming the terminal by removing a part of a lead frame by etching.
